(19) United States
(12) Patent Application Publication
(10) Pub. No.: US 2012/0150469 A1
(43) Pub. Date: Jun. 14, 2012

(54) ELECTRONIC DEVICE COOLING FAN TESTING

(75) Inventors: Dan Welter, Seattle, WA (US); Garrett Blankenburg, Seattle, WA (US)

(73) Assignee: MICROSOFT CORPORATION, Redmond, WA (US)

(21) Appl. No.: 12/965,099

(22) Filed: Dec. 10, 2010

(51) Int. Cl. G01R 23/16; G01R 23/00

(52) U.S. Cl. 702/77; 702/75; 702/76

(57) ABSTRACT

System and method implementations for testing a cooling fan in an electronic device are disclosed. As one example, a method of testing a cooling fan of a sample electronic device is disclosed that includes generating an audio input at an audio speaker and receiving an audio output at an audio microphone to obtain an audio output signal. The method further includes processing the audio output signal to identify frequency modulation in the audio output signal, and identifying a state of motion of fan blades of the cooling fan based, at least in part, on the frequency modulation.

Computers and other electronic devices generate heat during their operation, and the heat needs to be effectively dissipated to avoid damage and ensure reliable operation of the device. Accordingly, some electronic devices may include one or more cooling fans to regulate temperature of the electronic device. A cooling fan of an electronic device may be examined prior to delivery of the electronic device to a customer or occasionally during operation of the electronic device to ensure that the cooling fan is functioning properly. However, operation of a cooling fan that is located or embedded within an electronic device may be difficult to inspect, particularly where the surrounding environment contains substantial background noise, and/or when there is limited or no access to the internal structures or control mechanisms of the fan.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter, Furthermore, the claimed subject matter is not limited to implementations that solve any or all disadvantages noted in any part of this disclosure.

System and method implementations for testing a cooling fan in an electronic device are disclosed. As one example, disclosed is a method of testing a cooling fan of a sample electronic device that includes generating an audio input at an audio speaker and receiving an audio output at an audio microphone to obtain an audio output signal. The method further includes processing the audio output signal to identify frequency modulation in the audio output signal, and identifying a state of motion of fan blades of the cooling fan based, at least in part, on the frequency modulation.

### BRIEF DESCRIPTION OF DRAWINGS

FIG. 1 is a schematic diagram depicting an example system to test a cooling fan of an electronic device.

FIG. 2 is a flow diagram depicting an example method of testing a cooling fan of a sample electronic device.

FIG. 3 is a diagram depicting example data obtained from a prophetic test performed on a cooling fan of a sample electronic device.

### DETAILED DESCRIPTION

Rotational speed of fan blades of a cooling fan may be measured to identify a defect with the cooling fan or a defect with electronics driving the cooling fan. Cooling fans in some cases may not include on-board instrumentation for measuring the rotational speed of the fan blades. For example, a fan motor of the cooling fan may include two electrical connections with a power source rather than three electrical connections, thereby potentially precluding some approaches of directly measuring the fan blade rotational speed. Furthermore, a tachometer measurement of the fan blades may be difficult to perform if the cooling fan is tested when the electrical device is in a fully assembled or partially assembled state that reduces access to the cooling fan blades. Furthermore, ambient background noise may mask the operating sound of the cooling fan under some conditions, thereby potentially precluding other approaches of measuring fan speed.

In at least one implementation, an audio tone (e.g., a 16 kHz audio tone) is beamed at an electronic device from an audio speaker within an audio enclosure. An audio microphone within the audio enclosure receives the frequency modulated audio tone reflected from rotating fan blades of the cooling fan. Testing software may be used to perform a Fourier transform of audio output signals generated by the audio microphone to create a power spectrum. The rotating frequency of the fan blades may be inferred from the frequency modulation side lobes surrounding the 16 kHz carrier frequency. The disclosed testing implementations may enable a lower product cost for an electronic device since circuitry for measuring the cooling fan speed does not necessarily reside on-board the electronic device.

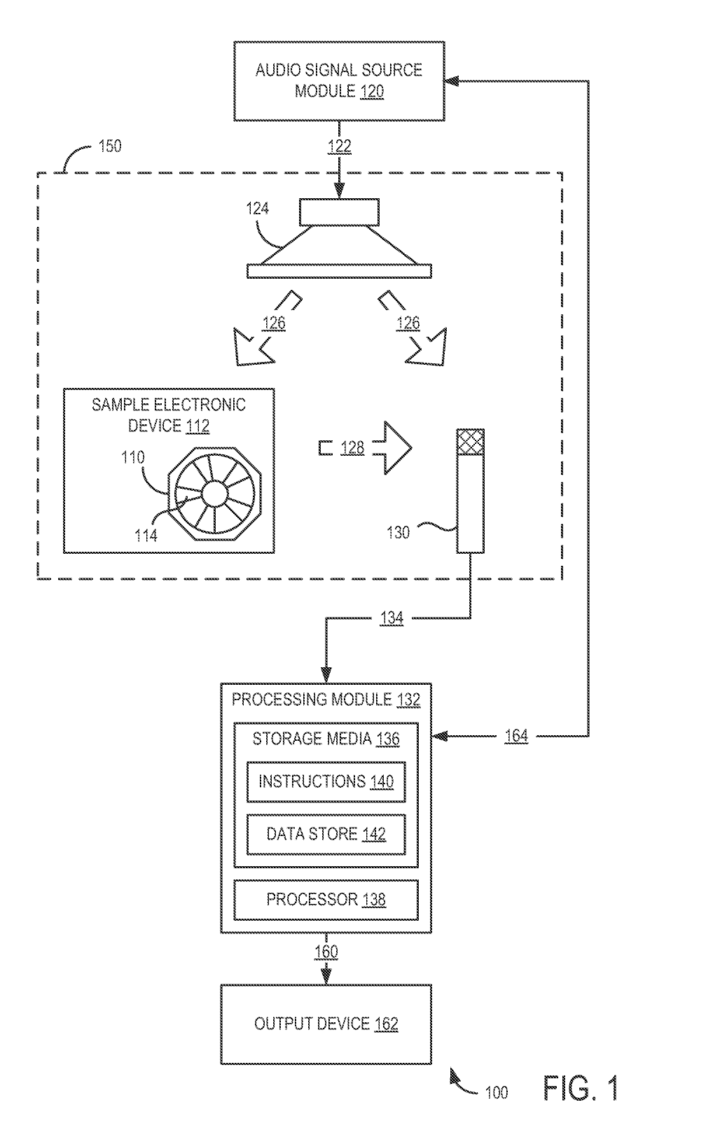

FIG. 1 is a schematic diagram depicting an example system 100 to test a cooling fan 110 of a sample electronic device 112 according to one implementation. System 100 comprises an audio signal source module 120 to generate an audio input signal 122. System 100 further comprises a first electro-acoustic transducer 124 operatively coupled to audio signal source module 120 to generate an audio input 126 responsive to audio input signal 122 generated by audio signal source module 120. In at least some implementations, first electro-acoustic transducer 124 may comprise an audio speaker.

Audio input 126 comprises physical acoustic waves generated by first electro-acoustic transducer 124. Audio input 126 may be reflected by fan blades 114 of cooling fan 110 as indicated by audio output 128. For example, as the fan blades rotate, they alternatively move toward and then away from first electro-acoustic transducer 124 in a sinusoidal manner. This in turn causes a positive, then a negative Doppler shift to the reflected acoustic waves of audio input 126. Accordingly, audio output 128 also comprises physical acoustic waves. The sinusoidally oscillating Doppler shift modulates the reflected acoustic waves as frequency modulation and is observable in a power spectrum as side lobes of the carrier frequency as depicted in greater detail by FIG. 3.

System 100 further comprises a second electroacoustic transducer 130. In at least some implementations, second electro-acoustic transducer 130 comprises an audio microphone. As depicted in FIG. 1, first electro-acoustic transducer 124 may be arranged at a first position relative to sample electronic device 112. Second electro-acoustic transducer 130 may be arranged at a second position relative to sample electronic device 112 that is different than the first position of first electro-acoustic transducer 124. In at least some implementations, sample electronic device 112 may be arranged substantially between the first position of first electro-acoustic transducer 124 and the second position of second electro-acoustic transducer 130.

System 100 further comprises a processing module 132 operatively coupled to second electro-acoustic transducer 130 to obtain an audio output signal 134 responsive to at least an audio output 128 received by second electro-acoustic transducer 130. in at least some implementations, processing module 132 is configured to identify a frequency modulation in audio output signal 134 and identify a state of motion of fan blades 114 of the cooling fan based, at least in part, on the frequency modulation.

As one example, processing module 132 may be configured to perform a Fourier transform of audio output signal 134 and identify the frequency modulation in audio output signal 134 to obtain an audio power spectrum of audio output signal 134. The audio power spectrum may comprise or indicate a carrier frequency and one or more frequency modulation side lobes of lesser audio power than the carrier frequency. Processing module 132 may identify the one or more frequency modulation side lobes of the carrier frequency of the audio output signal based, at least in part, on the audio power spectrum of audio output signal 134.

Processing module 132 may identify a frequency offset from the carrier frequency of the audio output signal and one or more of the frequency modulation side lobes. In at least some implementations, the state of motion of the fan blades of the cooling fan may be identified or computed by processing module 132 as a function of the frequency offset. The state of motion of the fan blades may include a rotational speed or a rate of rotation of the fan blades, for example. The processing module, for example, may compute the state of motion value as the rotational speed of fan blades 114 by dividing the frequency offset by a number of blades of fan blades 114. For example, if the frequency offset is 200 Hz and the cooling fan has five (5) fan blades, the 200 Hz modulating frequency will be five (5) times the rotational speed of the fan blades, which corresponds to a rotational frequency of 40 Hz or 2400 rpm.

In at least some implementations, processing module 132 may output the state of motion value as an output 160 that indicates the state of motion value. Output 160 may be interpreted by a human user via an output device 162, for example. Output device 162 may comprise a graphical display, a printer, an audio speaker, or other suitable output device. In at least some implementations, processing module 132 may store the state of motion value in a data store such as example data store 142 of storage media 136. In at least some implementations, processing module 132 may be configured to identify whether fan blades 114 have a rate of rotation that exceeds a threshold rate of rotation, and may indicate whether the rate of rotation exceeds the threshold rate of rotation. As one example, output 160 may indicate whether the rate of rotation of fan blades 114 exceeds the threshold rate of rotation.

In at least some implementations, processing module 132 may comprise computer readable storage media 136 having instructions 140 stored thereon executable by one or more processors, such as example processor 138 to perform one or more operations, processes, or methods described herein. Additionally or alternatively, instructions 140 may be executed by one or more hardware or firmware logic machines. Instructions 140 may comprise one or more computer programs, for example. It is to be understood that different modules, programs, and/or engines may he instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” are meant to encompass individual or groups of executable files, data files, libraries, drivers, scripts, database records, etc.

In at least some implementations, storage media 136 may include removable media and/or built-in devices, Storage media 136 may include optical memory devices (e.g., CD, DVD, HD-DVD, Blu-Ray Disc, etc.), semiconductor memory devices (e.g., RAM, EPROM, EEPROM, etc.) and/or magnetic memory devices (e.g., hard disk drive, floppy disk drive, tape drive, MRAM etc.), among others. Storage media 136 may include devices with one or more of the following characteristics: volatile, nonvolatile, dynamic, static, read/write, read-only, random access, sequential access, location addressable, file addressable, and content addressable.

As one example, instructions 140 may be executed by processor 138 to supply, responsive to control signal 164 provided to audio signal source module 120, audio input signal 122 to first electro-acoustic transducer 124 to generate audio input 126. Instructions 140 may be further executed by processor 138 to obtain audio output signal 134 generated by second electro-acoustic transducer 130 in response to second electro-acoustic transducer 130 receiving audio input 126 generated by first electro-acoustic transducer as audio output 128. Instructions 140 may be further executed by processor 138 to process audio output signal 134 to identify a rate of rotation of a mechanical element (e.g., fan blades 114 or other suitable mechanical element undergoing motion) located between first electro-acoustic transducer 124 and second electro-acoustic transducer 130.

Processing module 132 may compute the rate of rotation of the mechanical element based, at least in part, on a frequency offset between a carrier frequency of the audio output signal and one or more frequency modulation side lobes of the carrier frequency. For example, instructions 140 may be further executed by processor 138 to perform a Fourier transform of audio output signal 134 to identify the one or more frequency modulation side lobes of the carrier frequency of audio output signal 134 based, at least in part, on an audio power spectrum of the audio output signal.

Instructions 140 may be further executed by processor 138 to compare the rate of rotation of the mechanical element to a threshold rate of rotation, and indicate whether the rate of rotation of the mechanical element is greater than or less than the threshold rate of rotation. For example, instructions 140 may be further executed by processor 138 to output an indication of the rate of rotation of the mechanical element and/or an indication of whether the rate of rotation of the mechanical element is greater than or less than the threshold rate of rotation.

In at least some implementations, audio signal source module 120 is configured to generate audio input signal 122 having a substantially constant carrier frequency. As one example, the carrier frequency of the audio input signal and audio input may be selected to be less than a frequency response of first electro-acoustic transducer 124 and/or greater than a threshold factor (e.g., 1, 1.2, 2, 3, 10, 100 or more times) of a physical dimension (e.g., length, diameter, etc.) of fan blades 114 of cooling fan 110. As another example, the audio input signal and audio input may be generated at first electro-acoustic transducer 124 may have a carrier frequency in a range of 14 kHz-17 kHz. For example, a carrier frequency of 16 kHz may be generated by first electro-acoustic transducer 124. However, any suitable audio input signal and audio input having a constant or variable frequency, or set of frequencies may be utilized.

In at least some implementations, audio signal source module 120 may be configured to receive a control signal 164 from another source, such as processing module 132, for example. Control signal 164 may be varied (e.g., by processing module 132 or other source) to control audio input signal 122 (e.g., a frequency of audio input signal 122) to in turn control audio input 126.

In at least some implementations, system 100 may further comprise an acoustic enclosure 150 substantially surrounding at least first electro-acoustic transducer 124, second electroacoustic transducer 130, and sample electronic device 112. Acoustic enclosure 150 may at least partially reduce a background noise level at sample electronic device 112 and/or second electro-acoustic transducer 130 that may be otherwise present in the surrounding environment.

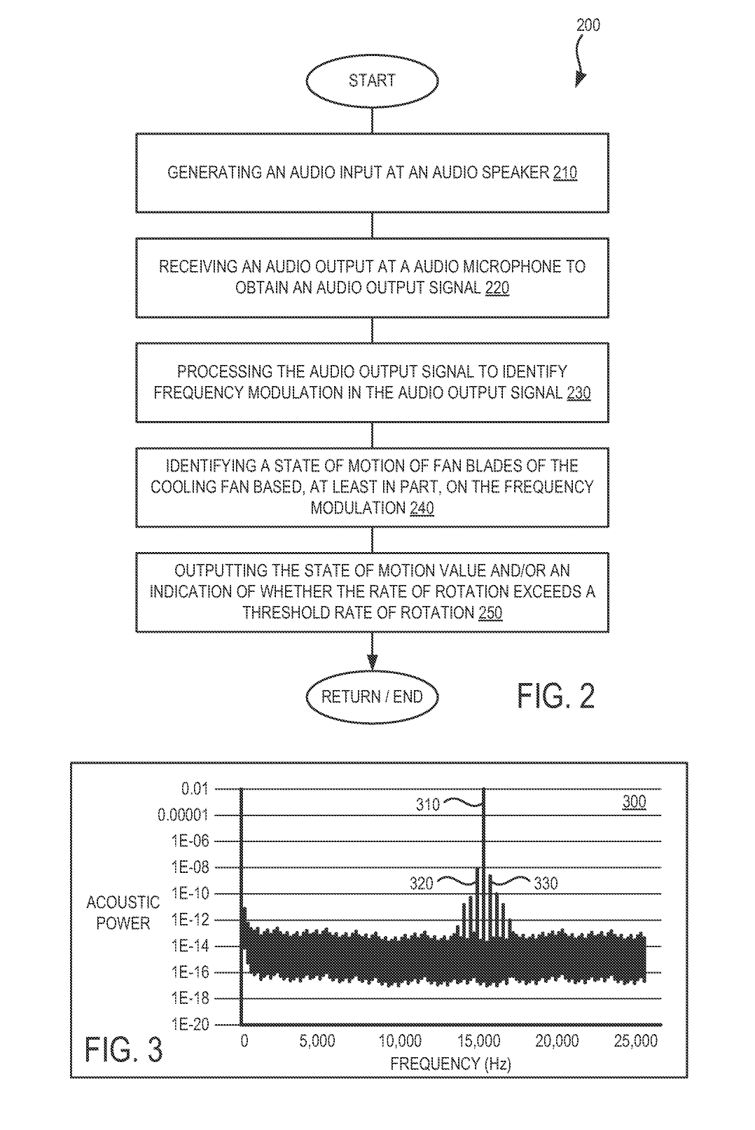

FIG. 2 is a flow diagram depicting an example method 200 of testing a cooling fan of a sample electronic device according to one implementation. As one example, method 200 may be performed by or using previously described system 100 of FIG. 1. Method 200 may be performed during manufacture of the electronic device before the electronic device is delivered to a customer, for example.

Operation 210 comprises generating an audio input at a first electro-acoustic transducer. As one example, the first electro-acoustic transducer comprises an audio speaker. In at least some implementations, generating the audio input at the first electroacoustic transducer comprises generating an audio input having a substantially constant carrier frequency. As one example, the carrier frequency of the audio input may be selected to be less than a frequency response of the first electro-acoustic transducer and/or greater than a threshold factor of a physical dimension of the fan blades of the cooling fan. As another example, generating the audio input at the first electro-acoustic transducer may comprise generating an audio input having a. carrier frequency in a range of 14 kHz-17 kHz. For example, the carrier frequency may be 16 kHz. However, other suitable frequencies or set of frequencies may be utilized.

Operation 220 comprises receiving an audio output at a second electro-acoustic transducer to obtain an audio output signal. The second electro-acoustic transducer may comprise an audio microphone, for example. The audio output may comprise acoustic waves of the audio input reflected from fan blades of the cooling fan of the sample electronic device.

In at least some implementations, method 200 may further comprise locating the sample electronic device substantially between a first position of the first electro-acoustic transducer and a second position of the second electro-acoustic transducer.

Operation 230 comprises processing the audio output signal to identify frequency modulation in the audio output signal. As one example, processing the audio output signal to identify frequency modulation may comprise comparing the audio output signal to an audio input signal used for generating the audio input at the first electro-acoustic transducer. As another example, processing the audio output signal to identify frequency modulation may comprise performing a Fourier transform of the audio output signal to obtain an audio power spectrum of the audio output signal. The audio power spectrum of the audio output signal may comprise the carrier frequency and one or more frequency modulation side lobes of lesser audio power than the carrier frequency.

Operation 240 comprises identifying a state of motion of the fan blades of the cooling fan based, at least in part, on the frequency modulation. In at least some implementations, identifying the state of motion of the fan blades of the cooling fan based, at least in part, on the frequency modulation may comprise: (1) identifying the one or more frequency modulation side lobes of the carrier frequency of the audio output signal based, at least in part, on the audio power spectrum of the audio output signal, and (2) identifying a frequency offset from the carrier frequency of the audio output signal and the one or more of the frequency modulation side lobes. The state of motion of the fan blades of the cooling fan may be computed, determined, or otherwise identified as a function of the frequency offset.

The state of motion of the fan blades may include a rotational speed of the fan blades, whereby operation 240 comprises computing the state of motion value as the rotational speed of the fan blades by dividing the frequency offset by the number of fan blades. The state of motion of the fan blades may include a rate of rotation of the fan blades, whereby operation 240 comprises identifying the state of motion of the fan blades of the cooling fan based, at least in part, on the frequency modulation. In at least some implementations, operation 240 may further comprise identifying whether the fan blades have a rate of rotation that exceeds a threshold rate of rotation.

Operation 250 comprises outputting one or more of the state of motion value and/or an indication of whether the rate of rotation of the fan blades exceeds the threshold rate of rotation. As one example, the state of motion value or the indication may be outputted via an output device, such as a graphical display, printer, or audio speaker, for example. In at least some implementations, the state of motion value or the indication may be stored at a data store of a computer readable storage media.

FIG. 3 is a diagram depicting example data 300 obtained from a prophetic test performed on a cooling fan of a sample electronic device according to one implementation. Data 300 is represented by a graph depicting a plot of acoustic power vs. frequency frequency vs. acoustic power of an audio power spectrum of an example audio output signal. A carrier frequency of the audio output signal is depicted at 310. Side lobes of carrier frequency 310 are depicted at 320 and 330 having approximately 60 dB lower magnitude, but are still detectable in relation to the signal to noise ratio of data 300. In this particular example, the carrier frequency corresponds to a 16 kHz carrier frequency and the side lobes 320 and 330 have a frequency offset of +/−200 Hz relative to the 16 kHz carrier frequency.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

The subject matter of the present disclosure includes all novel and nonobvious combinations and subcombinations of the various processes, systems and configurations, and other features, functions, acts, and/or properties disclosed herein, as well as any and all equivalents thereof.

1. A method of testing a cooling fan of a sample electronic device, comprising:
generating an audio input at an audio speaker;
receiving an audio output at an audio microphone to obtain an audio output signal;
processing the audio output signal to identify frequency modulation in the audio output signal; and
identifying a state of motion of fan blades of the cooling fan based, at least in part, on the frequency modulation.

2. The method of claim 1, wherein generating the audio input at the audio speaker comprises generating an audio input having a substantially constant carrier frequency.

3. The method of claim 2, wherein the carrier frequency of the audio input is selected to he less than a frequency response of the audio speaker and greater than a threshold factor of a physical dimension of the fan blades of the cooling fan.

4. The method of claim 1, wherein generating the audio input at the audio speaker comprises generating an audio input having a carrier frequency in a range of 14 kHz-17 kHz.

5. The method of claim 1, wherein processing the audio output signal to identify frequency modulation comprises comparing the audio output signal to an audio input signal used for generating the audio input at the audio speaker.

6. The method of claim 1, wherein processing the audio output signal to identify frequency modulation comprises performing a Fourier transform of the audio output signal to obtain an audio power spectrum of the audio output signal comprising a carrier frequency and one or more frequency modulation side lobes of lesser audio power than the carrier frequency.

7. The method of claim 6, wherein identifying the state of motion of fan blades of the cooling fan based, at least in part, on the frequency modulation further comprises:
identifying the one or more frequency modulation side lobes of the carrier frequency of the audio output signal based, at least in part, on the audio power spectrum of the audio output signal; and
identifying a frequency offset from the carrier frequency of the audio output signal and the one or more of the frequency modulation side lobes;
wherein the state of motion of the fan blades of the cooling fan is a function of the frequency offset.

8. The method of claim 6, wherein the state of motion of the fan blades is a rotational speed of the fan blades, the method further comprising:
computing the state of motion value as the rotational speed of the fan blades by dividing the frequency offset by a number of blades of the fan blades; and
outputting the state of motion value.

9. The method of claim 1, wherein the audio speaker is located at a first position relative to the sample electronic device and wherein the audio microphone is located at a second position relative to the sample electronic device, wherein the first position is different than the second position, the method further comprising:
locating the sample electronic device substantially between the first position of the audio speaker and the second position of the audio microphone.

10. The method of claim 1, wherein the state of motion of the fan blades is a rate of rotation of the fan blades; and
wherein identifying the state of motion of the fan blades of the cooling fan based, at least in part, on the frequency modulation comprises identifying whether the fan blades have a rate of rotation that exceeds a threshold rate of rotation;
wherein the method further comprises indicating whether the rate of rotation exceeds the threshold rate of rotation.

11. A system to test a cooling fan of a sample electronic device, comprising:
an audio signal source module to generate an audio input signal;
an audio speaker operatively coupled to the audio signal source module to generate an audio input responsive to the audio input signal generated by the audio signal source module;
an audio microphone to receive an audio output; and
a processing module operatively coupled to the audio microphone to:
obtain an audio output signal responsive to the audio output received by the audio microphone,
identify a frequency modulation in the audio output signal, and
identify a state of motion of fan blades of the cooling fan based, at least in part, on the frequency modulation.

12. The system of claim 11, further comprising:
an acoustic enclosure substantially surrounding at least the audio speaker, the audio microphone, and the sample electronic device.

13. The system of claim 11, the audio speaker located at a first position relative to the sample electronic device and the audio microphone located at a second position relative to the sample electronic device, wherein the first position is different than the second position.

14. The system of claim 11, wherein the audio signal source module is configured to generate an audio input signal having a substantially constant carrier frequency.

15. The system of claim 14, wherein the carrier frequency of the audio input signal is selected to be less than a frequency response of the audio speaker and greater than a threshold factor of a physical dimension of the fan blades of the cooling fan.

16. The system of claim 11, wherein the processing module is further configured to:
identify the frequency modulation in the audio output signal via a Fourier transform of the audio output signal to obtain an audio power spectrum of the audio output signal comprising a carrier frequency and one or more frequency modulation side lobes of lesser audio power than the carrier frequency;
identify the one or more frequency modulation side lobes of the carrier frequency of the audio output signal based, at least in part, on the audio power spectrum of the audio output signal;
identify a frequency offset from the carrier frequency of the audio output signal and the one or more of the frequency modulation side lobes, wherein the state of motion of the fan blades of the cooling fan is a function of the frequency offset.

17. The system of claim 16, wherein the state of motion of the fan blades is a rotational speed of the fan blades, and wherein the processing module is further configured to:
compute the state of motion value as the rotational speed of the fan blades by dividing the frequency offset by a number of blades of the fan blades; and
outputting the state of motion value.

18. The system of claim 11, wherein the state of motion of the fan blades is a rate of rotation of the fan blades, and wherein the processing module is further configured to:
identify whether the fan blades have a rate of rotation that exceeds a threshold rate of rotation; and
indicate whether the rate of rotation exceeds the threshold rate of rotation.

19. A computer readable storage medium having instructions stored thereon executable by one or more processors to:
supply an audio input signal to an audio speaker to generate an audio input;
obtain an audio output signal generated by an audio microphone in response to the audio microphone receiving the audio input generated by the audio speaker as an audio output;
process the audio output signal to identify a rate of rotation of a mechanical element located between the audio speaker and the audio microphone, the rate of rotation of the mechanical element based, at least in part, on a frequency offset between a carrier frequency of the audio output signal and one or more frequency modulation side lobes of the carrier frequency; and
perform a Fourier transform of the audio output signal to identify the one or more frequency modulation side lobes of the carrier frequency of the audio output signal based, at least in part, on an audio power spectrum of the audio output signal.

20. The computer readable storage media of claim 19, wherein the instructions are further executable by the one or more processors to:
compare the rate of rotation of the mechanical element to a threshold rate of rotation; and
indicate whether the rate of rotation of the mechanical element is greater than or less than the threshold rate of rotation.
